(19) United States
(12) Patent Application Publication
(10) Pub. No.: US 2022/0046833 A1
(43) Pub. Date: Feb. 10, 2022

(54) ELECTRONIC DEVICE

(71) Applicant: PEGATRON CORPORATION, Taipei City (TW)

(72) Inventors: Ruo-Tian Bai, TAIPEI CITY (TW); Jia-Xiong Li, TAIPEI CITY (TW)

(73) Assignee: PEGATRON CORPORATION, TAIPEI CITY (TW)

(21) Appl. No.: 17/356,284

(22) Filed: Jun. 23, 2021

(30) Foreign Application Priority Data
Aug. 10, 2020 (TW) 109210314

(51) Int. Cl. H05K 7/20; H05K 5/02

(52) U.S. Cl. CPC H05K 7/20972; G06F 1/163; H05K 5/0213

(57) ABSTRACT

An electronic device includes a casing, a heat generating element, a heat dissipation plate, and a centrifugal fan. The casing has a front side, a rear side, a peripheral side, and a plurality of vents. The peripheral side is located between the front side and the rear side, and the vents are distributed on the peripheral side. The heat generating element and the heat dissipation plate are disposed in the casing, and the heat generating element covers the heat generating element. Heat generated by the heating generating element is conducted to the heat dissipation plate. The centrifugal fan is disposed in the casing and is located on a same side of the heat generating element and the heat dissipation plate. The centrifugal fan is adapted for omnidirectional air discharge and an airflow generated from the centrifugal fan dissipates the heat out of the casing through the vents.

### CROSS-REFERENCE TO RELATED APPLICATION

This application claims the priority benefit of Taiwanese application no. 109210314, filed on Aug. 10, 2020. The entirety of the above-mentioned patent application is hereby incorporated by reference herein and made a part of this specification.

### BACKGROUND

### Technical Field

The disclosure relates to an electronic device, and in particular, to an electronic device applied in virtual reality.

### Description of Related Art

The so-called virtual reality refers to the use of computer simulation to generate a three-dimensional virtual environment so that users acquire an immersive sense of presence. Generally speaking, the users require to wear a head-mounted display device to view image frames of the three-dimensional virtual environment. The head-mounted display device may broadly include a display host and a headband, and the display host is configured to provide the image frames of the three-dimensional virtual environment.

Furthermore, a central processing unit (CPU), a graphics processing unit (GPU), an active element, and a passive element are disposed inside the display host, and generate heat during operation of the head-mounted display device.

In order to quickly discharge hot air inside the display host to the outside, in common practices, a fan and a heat pipe are mostly disposed inside the display host. However, the heat dissipation mechanism must take into account the extension path of the heat pipe, the number of heat pipes disposed, and the outlet path of the fan, resulting in overly high manufacturing costs, limited space for disposing elements, adversely affected heat dissipation efficiency, single heat dissipation path, and overly high temperature of a single block of the display host.

### SUMMARY

The disclosure provides an electronic device, which has high heat dissipation efficiency.

An electronic device of the disclosure includes a casing, a heat generating element, a heat dissipation plate, and a centrifugal fan. The casing has a front side, a rear side, a peripheral side, and a plurality of vents. The peripheral side is located between the front side and the rear side, and the vents are distributed on the peripheral side. The heat generating element and the heat dissipation plate are disposed in the casing, and the heat generating element covers the heat generating element. Heat generated by the heating generating element is conducted to the heat dissipation plate. The centrifugal fan is disposed in the casing and is located on a same side of the heat generating element and the heat dissipation plate. The centrifugal fan is adapted for omnidirectional air discharge and an airflow generated from the centrifugal fan dissipates the heat out of the casing through the vents.

Based on the foregoing, the electronic device of the disclosure adopts the centrifugal fan adapted for omnidirectional air discharge (or 360-degree air discharge). On the other hand, since the plurality of vents are distributed on the peripheral side of the casing of the display host, the airflow generated from the centrifugal fan flows out of the casing through the vents. That is to say, the casing is provided with a plurality of outlet paths to quickly dissipate the heat generated by the heat generating elements out of the casing. Therefore, the electronic device of the disclosure has high heat dissipation efficiency.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 and FIG. 2 are schematic views showing an electronic device according to an embodiment of the disclosure from two different view angles.

FIG. 3 is a schematic front view of the electronic device of FIG. 1.

FIG. 4 is a schematic cross-sectional view of the electronic device of FIG. 3 along section line I-I.

### DESCRIPTION OF THE EMBODIMENTS

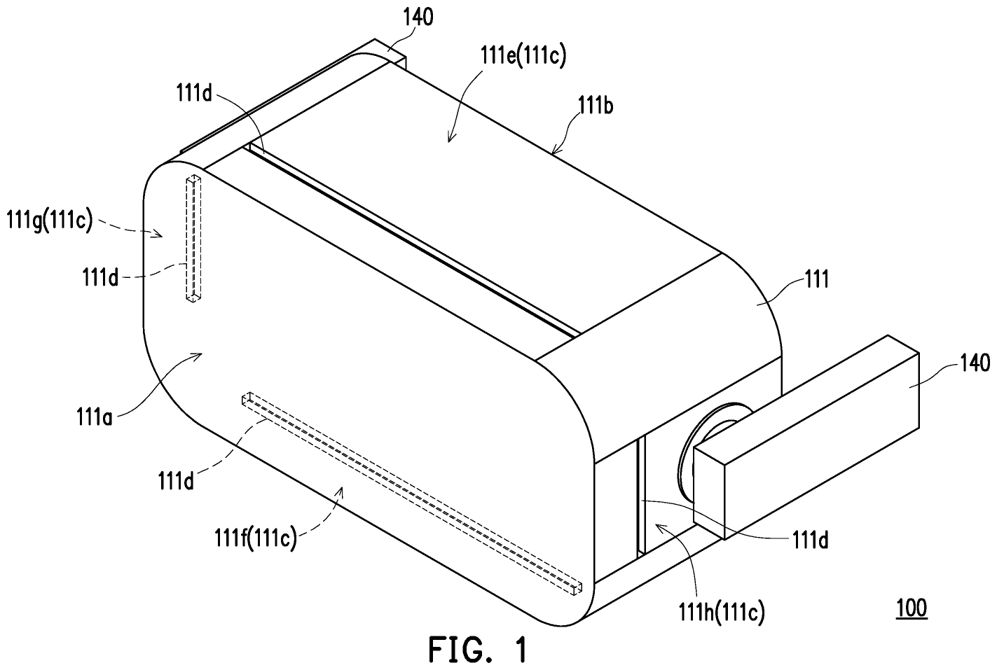

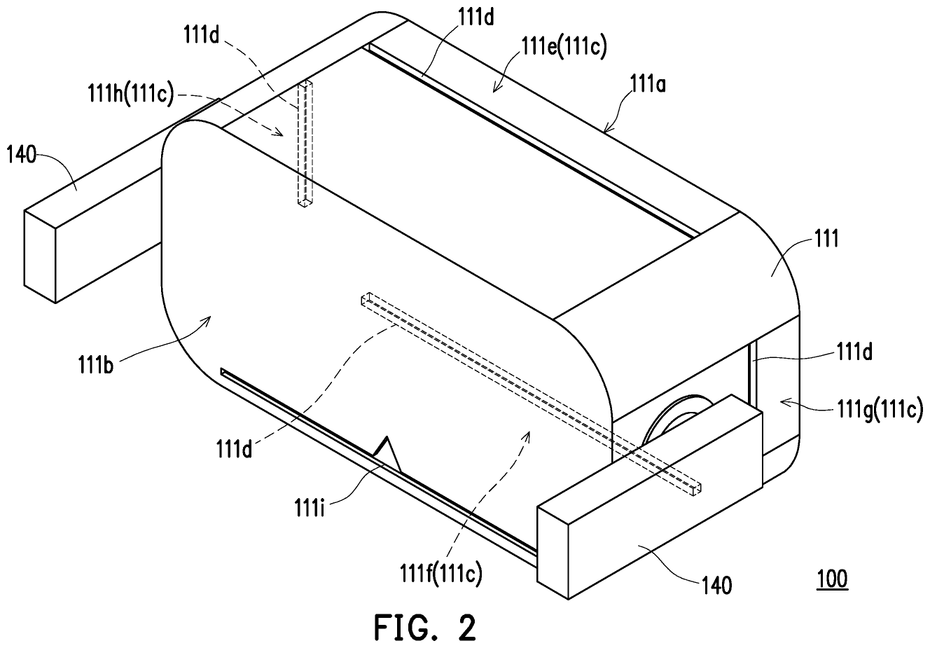

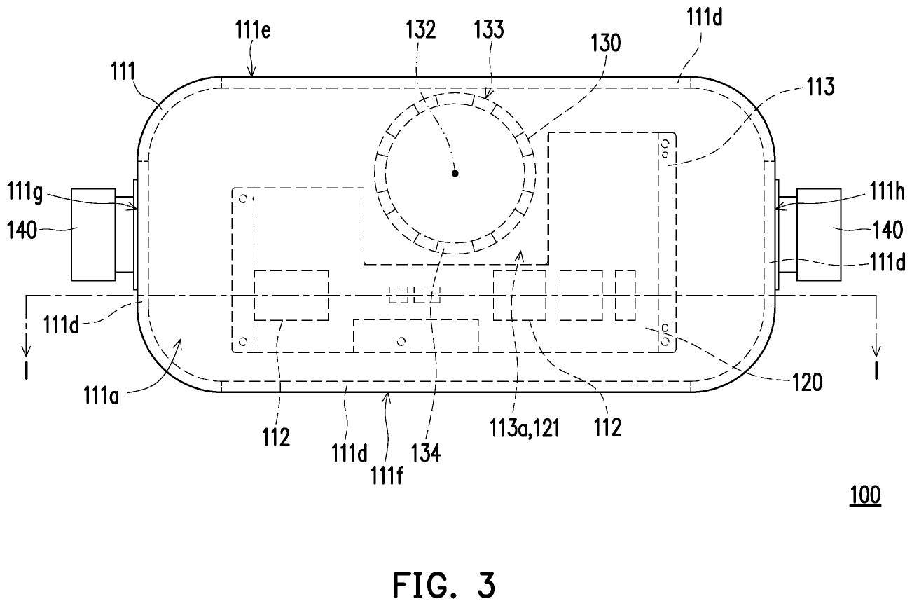

FIG. 1 and FIG. 2 are schematic views showing an electronic device according to an embodiment of the disclosure from two different view angles. FIG. 3 is a schematic front view of the electronic device of FIG. 1. With reference to FIG. 1 to FIG. 3, in this embodiment, an electronic device 100 includes a casing 111, heat generating elements 112, a heat dissipation plate 120, and a centrifugal fan 130. The heat generating elements 112, the heat dissipation plate 120, and the centrifugal fan 130 are disposed in the casing 111. Furthermore, the casing 111 has a front side 111a, a rear side 111b opposite to the front side 111a, a peripheral side 111c located between the front side 111a and the rear side 111b, and a plurality of vents 111d distributed on the peripheral side 111c. The peripheral side 111c is connected to the front side 111a and the rear side 111b. In addition, the centrifugal fan 130 during operation is adapted for driving high-temperature gas in the casing 111 (i.e., heat generated by the heat generating elements 112) to be discharged from the vents 111d. In some embodiments, the vents 111d are distributed on the peripheral side 111c and close to the front side 111a, so that when being dissipated out of the casing 111, the heat would not affect a user adjacent to the rear side 111b.

The electronic device 100 may be a head-mounted display device, and the rear side 111b thereof serves as an image-displaying side. When the user wears the electronic device 100, the face of the user is close to the rear side 111b. On the other hand, the peripheral side 111c includes an upper peripheral side 111e, a lower peripheral side 111f opposite to the upper peripheral side 111e, a left peripheral side 111g, and a right peripheral side 111h opposite to the left peripheral side 111g. The left peripheral side 111g and the right peripheral side 111h are located between the upper peripheral side 111e and the lower peripheral side 111f, and the left peripheral side 111g and the right peripheral side 111h are both connected to the upper peripheral side 111e and the lower peripheral side 111f. To be specific, the upper peripheral side 111e, the lower peripheral side 111f, the left peripheral side 111g, and the right peripheral side 111h are each provided with at least one vent 111d. That is to say, the at least four vents 111d are evenly distributed on the peripheral side 111c, and the casing 111 is provided with at least four outlet paths in different directions.

The heat dissipation plate 120 is configured to conduct the heat generated by the heat source (i.e., the heat generating elements 112), and perform heat exchange with the gas in the casing 111, so that the gas in the casing 111 is converted into high-temperature gas. More specifically, the centrifugal fan 130 may be configured to drawn low-temperature gas outside the casing 111 into the casing 111, and discharge the high-temperature gas in the casing 111 out of the casing 111. Furthermore, the centrifugal fan 130 is adapted for omnidirectional air discharge (or 360-degree air discharge), and an airflow generated from the centrifugal fan 130 flows out of the casing 111 through the vents 111d to discharge the high-temperature gas in the casing 111 out of the casing 111.

In this embodiment, the casing 111 is provided with at least four outlet paths in different directions. The airflow generated from the centrifugal fan 130 flows out of the casing 111 through the vent 111d on the upper peripheral side 111e, the vent 111d on the lower peripheral side 111f, the vent 111d on the left peripheral side 111g, and the vent 111d on the right peripheral side 111h to quickly discharge the high-temperature gas in the casing 111 out of the casing 111. Therefore, the electronic device 100 has high heat dissipation efficiency.

With reference to FIG. 3, the centrifugal fan 130 has a rotation axis 132, a peripheral surface 133, and a plurality of outlets 134. In addition, the peripheral surface 133 surrounds the rotation axis 132. On the other hand, the peripheral surface 133 faces the peripheral side 111c. The outlets 134 are distributed on the peripheral surface 133, and each of the vents 111d is disposed corresponding to at least one outlet 134. That is to say, the centrifugal fan 130 is provided with at least four outlet paths located in different directions. To be specific, during operation of the centrifugal fan 130, the airflow induced by the fan blades flows outward through the outlets 134 toward the vents 111d. In addition, a part of the airflow flowing outward from the outlets 134 flows through the heat dissipation plate 120 to increase heat exchange efficiency.

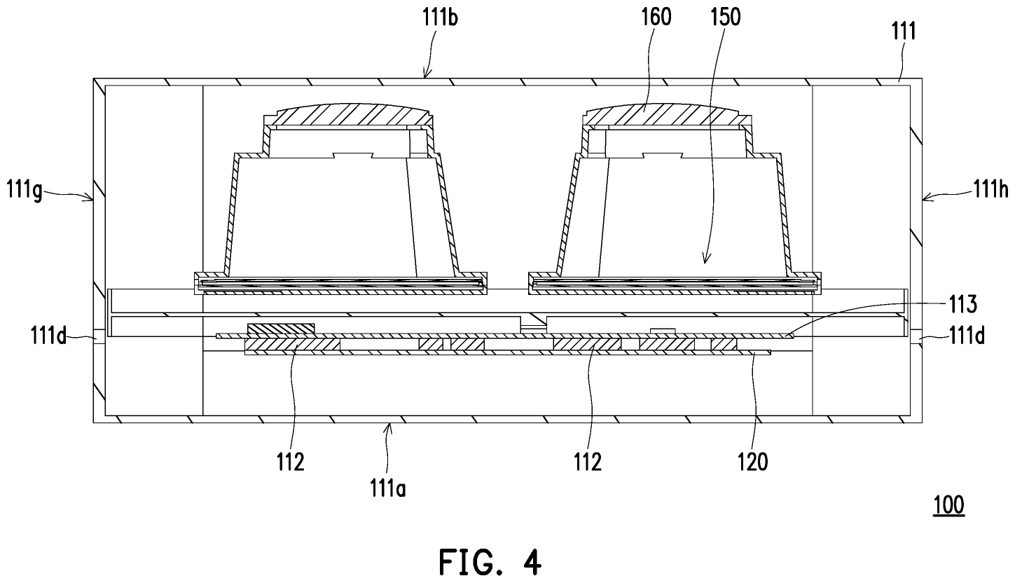

FIG. 4 is a schematic cross-sectional view of the electronic device of FIG. 3 along section line I-I. With reference to FIG. 3 and FIG. 4, in this embodiment, the heat generating elements 112 are the heat sources in the casing 111, such as a central processing unit (CPU), a graphics processing unit (GPU), an active element, or a passive element. On the other hand, the heat dissipation plate 120 may be made of metal, alloy, or other materials of high thermal conductivity, and be pasted or fixed to the heat generating elements 112 through an electrically insulating and thermally conductive adhesive (e.g., an electrically insulating and thermally conductive gasket, an insulating and thermally conductive adhesive, or a heat dissipation paste) to be thermally coupled to the heat generating elements 112 and conduct the heat generated by the heat generating elements 112. In addition, the heat dissipation plate 120 may be provided with heat dissipation fins to increase the heat exchange area.

The electronic device 100 further includes a circuit board 113. The heat generating elements 112 are disposed on the circuit board 113, and the heat generating elements 112 are located between the heat dissipation plate 120 and the circuit board 113. The heat dissipation plate 120 covers the heat generating elements 112. The centrifugal fan 130 is located on a same side of the heat generating elements 112 and the heat dissipation plate 120, and an area of the heat dissipation plate 120 is slightly smaller than an area of the circuit board 113. Furthermore, the heat dissipation plate 120 overlaps the circuit board 113. The heat dissipation plate 120 has a first recess 121, and the circuit board 113 has a second recess 113a that overlaps the first recess 121. At least part of the centrifugal fan 130 is located in the first recess 121 and the second recess 113a to maximize or optimize space for disposing elements in the casing 111. In addition, since the electronic device 100 is not provided with a heat pipe, the manufacturing costs can be reduced and the space for disposing elements in the casing 111 can be maximized or optimized.

In other embodiments, the area of the heat dissipation plate 120 may also be larger than the area of the circuit board 113. The area size of the heat dissipation plate 120 depends not only on the size of the system, but also on whether the heat dissipation plate 120 is sufficient to dissipate the heat generated by the system, and is thus not limited by the disclosure.

With reference to FIG. 1 and FIG. 2, in this embodiment, the casing 111 has an inlet 111i located on the rear side 111b. During operation of the centrifugal fan 130, the low-temperature gas outside the casing 111 flows into the casing 111 through the inlet 111i. In addition, an intake of the centrifugal fan 130 is disposed corresponding to the inlet 111i, so the intake of the centrifugal fan 130 faces the rear side 111b.

In other embodiments, the inlet 111i is located on the front side 111a. In addition, the intake of the centrifugal fan 130 is disposed corresponding to the inlet 111i, so the intake of the centrifugal fan 130 faces the front side 111a.

With reference to FIG. 1 and FIG. 2, in this embodiment, the electronic device 100 further includes a headband 140 connected to the peripheral side 111c of the casing 111, and connected to the left peripheral side 111g and the right peripheral side 111h, which is convenient for the user to wear the electronic device 100.

With reference to FIG. 4, the electronic device 100 further includes a display 150 and a lens 160. The display 150 and the lens 160 are disposed in the casing 111, and the lens 160 is located on a path of an image beam emitted by the display 150 to project the image beam to the eyes of the user. Since the rear side 111b of the casing 111 serves as the image-displaying side, the lens 160 is closer to the rear side 111b than the display 150 is.

In summary of the foregoing, the electronic device of the disclosure adopts the centrifugal fan adapted for omnidirectional air discharge (or 360-degree air discharge). On the other hand, since the plurality of vents are distributed on the peripheral side of the casing of the display host, the airflow generated from the centrifugal fan flows out of the casing through the vents. That is to say, the casing is provided with a plurality of outlet paths to quickly dissipate the heat generated by the heat generating elements out of the casing. Therefore, the electronic device of the disclosure has high heat dissipation efficiency.

In addition, the casing is provided with the multiple outlet paths, thus helping to avoid the situation that the temperature of a single block of the casing is too high. In addition, since the electronic device of the disclosure is not provided with a heat pipe, the manufacturing costs can be reduced and the space for disposing elements in the casing 111 can be maximized or optimized.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device, comprising:
a casing comprising a front side, a rear side, a peripheral side, and a plurality of vents, wherein the peripheral side is located between the front side and the rear side, and the vents are distributed on the peripheral side;
a heat generating element disposed in the casing and generating heat;
a heat dissipation plate disposed in the casing and covering the heat generating element, wherein the heat generated by the heat generating element is conducted to the heat dissipation plate; and
a centrifugal fan disposed in the casing and located on a same side of the heat generating element and the heat dissipation plate, wherein the centrifugal fan is adapted for omnidirectional air discharge, and an airflow generated from the centrifugal fan dissipates the heat out of the casing through the vents.

2. The electronic device according to claim 1, further comprising a circuit board, wherein the heat generating element is disposed on the circuit board, and the heat generating element is located between the heat dissipation plate and the circuit board.

3. The electronic device according to claim 2, wherein the heat dissipation plate has a first recess, the circuit board has a second recess, the first recess overlaps the second recess, and the centrifugal fan is located in the first recess and the second recess.

4. The electronic device according to claim 1, wherein the plurality of vents comprise four vents evenly distributed on the peripheral side.

5. The electronic device according to claim 1, wherein the vents are distributed on the peripheral side and close to the front side.

6. The electronic device according to claim 1, wherein the casing has an inlet located on the rear side, and the inlet is disposed corresponding to an intake of the centrifugal fan.

7. The electronic device according to claim 1, wherein the centrifugal fan has a rotation axis, a peripheral surface, and a plurality of outlets, the peripheral surface surrounds the rotation axis, the peripheral surface faces the peripheral side, the outlets are distributed on the peripheral surface, and the outlets are disposed corresponding to the vents.

8. The electronic device according to claim 1, further comprising a headband connected to the peripheral side of the casing.

9. The electronic device according to claim 1, further comprising a display and a lens, wherein the display and the lens are disposed in the casing, and the lens is adjacent to the rear side and is located on a path of an image beam emitted by the display.
